(19) United States
(12) Patent Application Publication
(10) Pub. No.: US 2024/0234704 A1
(43) Pub. Date: Jul. 11, 2024

(54) Black Phosphorus Anode Electrodes, Methods For Preparing The Same, And Lithium Ion Batteries

(71) Applicant: Shenzhen Hanke New Material Technology Co., Ltd., Shenzhen, Guangdong (CN)

(72) Inventors: Dian Yi, Dongguan, Guangdong (CN); Rongfu Wang, Shenzhen, Guangdong (CN)

(73) Assignee: Shenzhen Hanke New Material Technology Co., Ltd., Shenzhen, Guangdong (CN)

(21) Appl. No.: 18/007,976

(22) PCT Filed: Aug. 9, 2022
(86) PCT No.: PCT/CN2022/111244

§ 371 Date: Feb. 8, 2024

(30) Foreign Application Priority Data
Aug. 1, 2022 (CN) 202210914077.4

(51) Int. Cl. H01M 4/38; C01B 25/02; C23C 14/06; H01M 4/02; H01M 4/04; H01M 10/0525

(52) U.S. Cl. CPC H01M 4/38; C01B 25/02; C23C 14/06; H01M 4/0404; H01M 10/0525; H01M 2004/027

(57) ABSTRACT

The present disclosure relates to a black phosphorus anode electrode, including a current collector, an induction deposition layer, and a film of black phosphorus. The induction deposition layer is disposed on the current collector. The induction deposition layer includes a phosphorus-containing alloy configured to induce deposition of the film of black phosphorus. The film of black phosphorus is formed on the induction deposition layer by magnetron sputtering. The film of black phosphorus covers the current collector.

### CROSS-REFERENCE TO RELATED APPLICATIONS

The present application is a national phase entry under 35 U.S.C. § 371 of International Application No. PCT/CN2022/111244, filed Aug. 9, 2022, which claims priority to Chinese Patent Application No. 202210914077.4, filed on Aug. 1, 2022, entitled “BLACK PHOSPHORUS ANODE ELECTRODES, METHODS FOR PREPARING THE SAME, AND LITHIUM ION BATTERIES”, all of which are hereby incorporated herein by reference.

### TECHNICAL FIELD

The present disclosure relates to the technical field of batteries, and in particular to black phosphorus anode electrodes, methods for preparing the same, and lithium ion batteries.

### BACKGROUND

With the development of the world, the importance of electrochemical energy storage is increasing day by day. Lithium ion batteries store and release electrical energy due to the movement of lithium ions back and forth between the anode electrode and the cathode electrode. Since having relatively high energy density, long cycle life, and relatively mature production routes, lithium ion batteries have become the secondary batteries with the largest industrial scale at present.

In traditional lithium ion batteries, the material of the anode electrode is mainly graphite. Graphite has relatively limited capacity, which is gradually difficult to meet growing requirements on capacity. Black phosphorus is also an anode material of lithium ion batteries. Black phosphorus has a layer-stack structure. During charge and discharge, lithium ions are mainly transferred between the layers of black phosphorus, in which a complete discharge will yield lithium phosphide (Li₃P). The capacity of black phosphorus is as high as 2596 mAh·g⁻¹. In some previous studies, black phosphorus blocks and a conductive agent are usually mixed directly to form an anode electrode. However, during charge and discharge, the black phosphorus has severe volume change, and interior of the black phosphorus blocks has a poor conductivity. Thus, neither the discharge capacity nor the cycle stability of this anode electrode is satisfactory. The black phosphorus blocks are similar to graphite in appearance, performance, and structure, and also have an exfoliatable layered structure, which can form multi-layer nanosheets of black phosphorus by exfoliation. Black phosphorus nanosheets can overcome the problems existing in the black phosphorus blocks to a certain extent, so there are also attempts to use black phosphorus nanosheet powder as the anode active material of the lithium ion batteries in some further researches. For example, it is proposed to blend black phosphorus nanomaterials with the material such as graphene to improve the capacity and cycle stability of black phosphorus. This can increase the specific discharge capacity of black phosphorus anode electrode to 900 mAh·g⁻¹ or above, which however is still far to the theoretical specific capacity. In addition, the cycle stability of the black phosphorus anode electrode is also poor and needs to be further improved.

### SUMMARY

According to some embodiments of the present disclosure, a black phosphorus anode electrode is provided. The black phosphorus anode electrode includes a current collector, an induction deposition layer, and a film of black phosphorus. The induction deposition layer is disposed on the current collector. The induction deposition layer includes a phosphorus-containing alloy configured to induce deposition of the film of black phosphorus. The film of black phosphorus is formed on the induction deposition layer by magnetron sputtering. The film of black phosphorus covers the current collector.

In some embodiments of the present disclosure, a thickness of the film of black phosphorus is 1 μm to 50 μm.

In some embodiments of the present disclosure, the film of black phosphorus is one or more films of black phosphorus, and lateral dimension of each of the one or more films of black phosphorus is larger than or equal to 100 μm.

In some embodiments of the present disclosure, the induction deposition layer comprises a plurality of induction nucleation parts spaced apart from each other, each of the plurality of induction nucleation parts comprises the phosphors-containing alloy, and the current collector is exposed between the plurality of the induced nucleation parts.

In some embodiments of the present disclosure, a thickness of the induction deposition layer is smaller than or equal to 5 nm.

In some embodiments of the present disclosure, the film of black phosphorus further comprises a laser-ablated hole.

In some embodiments of the present disclosure, the laser-ablated hole is a plurality of laser-ablated holes, and a diameter of each of the plurality of laser-ablated holes is smaller than or equal to 0.1 mm.

In some embodiments of the present disclosure, the induction deposition layer and the film of black phosphorus are disposed on each of opposite surfaces of the current collector.

According to some other embodiments of the present disclosure, a method for preparing a black phosphorus anode electrode, the black phosphorus anode electrode comprising a current collector, an induction deposition layer, and a film of black phosphorus, wherein the induction deposition layer is disposed on the current collector, the induction deposition layer comprises a phosphorus-containing alloy configured to induce deposition of the film of black phosphorus, the film of black phosphorus is formed on the induction deposition layer by magnetron sputtering, and the film of black phosphorus covers the current collector; the method comprising following steps:
forming the induction deposition layer on the current collector;
disposing the current collector formed with the induction deposition layer in a magnetron sputtering chamber, and depositing the film of black phosphorus on the induction deposition layer by magnetron sputtering.

In some embodiments of the present disclosure, a thickness of the film of black phosphorus is 1 μm to 50 μm.

In some embodiments of the present disclosure, the film of black phosphorus is one or more films of black phosphorus, and lateral dimension of each of the one or more films of black phosphorus is larger than or equal to 100 μm.

In some embodiments of the present disclosure, the induction deposition layer comprises a plurality of induction nucleation parts spaced apart from each other, each of the plurality of induction nucleation parts comprises the phosphors-containing alloy, and the current collector is exposed between the plurality of the induced nucleation parts.

In some embodiments of the present disclosure, a thickness of the induction deposition layer is smaller than or equal to 5 nm.

In some embodiments of the present disclosure, the film of black phosphorus further comprises a laser-ablated hole.

In some embodiments of the present disclosure, the laser-ablated hole is a plurality of laser-ablated holes, and a diameter of each of the plurality of laser-ablated holes is smaller than or equal to 0.1 mm.

In some embodiments of the present disclosure, the induction deposition layer and the film of black phosphorus are disposed on each of opposite surfaces of the current collector.

According to yet another some embodiments of the present disclosure, a lithium ion battery comprising a cathode electrode, a separator and an anode electrode, wherein the cathode electrode and the anode electrode are opposite to each other, the separator is disposed between the cathode electrode and the anode electrode, the anode electrode is a black phosphorus anode electrode, and the black phosphorus anode electrode comprises a current collector, an induction deposition layer, and a film of black phosphorus, the induction deposition layer is disposed on the current collector, the induction deposition layer comprises a phosphorus-containing alloy configured to induce deposition of the film of black phosphorus, the film of black phosphorus is formed on the induction deposition layer by magnetron sputtering, and the film of black phosphorus covers the current collector.

In some embodiments of the present disclosure, a thickness of the film of black phosphorus is 1 μm to 50 μm.

In some embodiments of the present disclosure, the film of black phosphorus is one or more films of black phosphorus, and lateral dimension of each of the one or more films of black phosphorus is larger than or equal to 100 μm.

In some embodiments of the present disclosure, the induction deposition layer comprises a plurality of induction nucleation parts spaced apart from each other, each of the plurality of induction nucleation parts comprises the phosphors-containing alloy, and the current collector is exposed between the plurality of the induced nucleation parts.

In some embodiments of the present disclosure, a thickness of the induction deposition layer is smaller than or equal to 5 nm.

In some embodiments of the present disclosure, the film of black phosphorus further comprises a laser-ablated hole.

In some embodiments of the present disclosure, the laser-ablated hole is a plurality of laser-ablated holes, and a diameter of each of the plurality of laser-ablated holes is smaller than or equal to 0.1 mm.

In some embodiments of the present disclosure, the induction deposition layer and the film of black phosphorus are disposed on each of opposite surfaces of the current collector.

The details of one or more embodiments of the present disclosure are set forth in the accompanying drawings and the description below. Other features, objects and advantages of the present disclosure will become apparent from the description and claims.

### DETAILED DESCRIPTION

In order to facilitate the understanding of the present disclosure, the present disclosure will be comprehensively described with reference to the drawings. Embodiments of the disclosure are shown in the accompanying drawings. However, the present disclosure can be implemented in many different forms and therefore is not limited to the embodiments described herein. It is to be understood that the purpose of providing these embodiments is to make the understanding of the present disclosure more thorough and comprehensive.

In addition, the terms “first” and “second” are merely used for descriptive purposes, and should not be construed as indicating or implying relative importance or implying the quantity or order of the described technical features. Therefore, the feature modified by “first” or “second” may explicitly or implicitly includes at least one of the feature. In the description of the present disclosure, “a plurality of” means at least two, such as two, three, etc., unless otherwise expressly and specifically defined.

In describing positional relationships, when an element such as a layer, film or substrate is referred to as being “on” another layer, it can be directly on the other layer, or intermediate layers may also be present, unless otherwise specified. Further, when a layer is referred to as being “below” another layer, it can be directly under the other layer, or one or more intermediate layers may also be present. It can also be understood that when a layer is referred to as being “between” two layers, it can be the only layer between the two layers, or one or more intermediate layers may also be present.

Unless stated to the contrary, terms in singular form are intended to include the plural form as well, and should not be construed that the quantity is only one.

Unless otherwise specified, all the technical and scientific terms herein shall be understood as the same meaning with those commonly accepted by a person skilled in the art. Such terms, as used herein, are for the purpose of describing exemplary examples of, and without limiting, the present disclosure.

According to some embodiments of the present disclosure, a black phosphorus anode electrode is provided. The black phosphorus anode electrode includes a current collector, an induction deposition layer, and a film of black phosphorus. The induction deposition layer is disposed on the current collector. The induction deposition layer includes a phosphorus-containing alloy configured to induce deposition of the film of black phosphorus. The film of black phosphorus is formed on the induction deposition layer by magnetron sputtering. The film of black phosphorus covers the current collector.

In the above-described black phosphorus anode electrode, the induction deposition layer configured to induce deposition of black phosphorus is disposed on the current collector. The film of black phosphorus is formed on a surface of the induction deposition layer by magnetron sputtering, so that the film of black phosphorus is directly grown on a surface of the current collector. In the embodiment of the black phosphorus anode electrode, the technical idea of directly depositing the film of black phosphorus on the current collector as an active material is proposed for the first time. The grown film of black phosphorus is relatively integrated and includes pores as well. Compared with the traditional technology of using the mixture of black phosphorus nanosheets and graphene as the anode electrode material, the embodiment of the black phosphorus anode electrode has at least the following advantages.

On the one hand, the layered film of black phosphorus grown directly on the current collector has stronger electron transferability in its interior, which ensures the electron conduction ability of the interior of the film of black phosphorus. Furthermore, the electrical contact area between the film of black phosphorus as a whole and the current collector is larger, which ensures the electron conduction ability between the film of black phosphorus and the current collector. More importantly, the film of black phosphorus grown on the induction deposition layer through the magnetron sputtering is porous, so that the prepared film of black phosphorus is relatively loose while having integrity. The pores can buffer the volume change of the film of black phosphorus in the electrochemical reaction to a certain extent, which further reduce the detachment of the active material from the surface of the current collector due to the repeated expansion and contraction.

In traditional technology, the film of black phosphorus is mostly prepared by chemical vapor deposition. However, the film of black phosphorus prepared by the chemical vapor deposition is very dense. When the dense film is used as an anode electrode material, it will generate a large structural deformation due to the expansion and contraction of the volume, and therefore is detached quickly from the current collector, so the dense film may be not suitable as the anode electrode material. The inventors of the present disclosure have found through research that, compared with the chemical vapor deposition method, the magnetron sputtering method can grow a film of black phosphorus with smaller density on the induction deposition layer. The film of black phosphorus includes pores and is relatively loose, and therefore is capable of accommodating the volume expansion of black phosphorus in charge and discharge, and thus ensures the normal use of the film of black phosphorus.

In some specific examples of the present embodiment, the density of the film of black phosphorus is controlled to be 20% to 60% of the density of black phosphorus crystal. It can be understood that in an actual preparation process, the density of the film of black phosphorus can be controlled by controlling the parameters of the magnetron sputtering, such as the bias voltage, power, and target material.

In a specific example, the density of the film of black phosphorus can be controlled by controlling the bias voltage and/or the power of the magnetron sputtering. For example, relatively low or relatively high bias voltage will both lead to a lower density of film of black phosphorus.

The induction deposition layer is used as a nucleation substrate of the film of black phosphorus to grow. When the phosphorus atoms are bombarded from a phosphorus target and come into contact with the induction deposition layer, the induction deposition layer becomes the nucleation site for epitaxial growth of the film of black phosphorus. It can be understood that the exposed crystal plane of the material of the induction deposition layer should be matched with a crystal plane of black phosphorus, so as to facilitate the epitaxial growth of the film of black phosphorus.

In some specific examples of the present embodiment, the induction deposition layer includes a plurality of induction nucleation parts spaced apart from each other. The current collector is exposed between the induction nucleation parts. When the induction deposition layer includes the plurality of spaced induction nucleation parts, phosphorus atoms will be deposited on the surface of each induction nucleation part to form the film of black phosphorus. Since black phosphorus has a layered structure, the film of black phosphorus will grow and expand from the induction nucleation parts to the surrounding areas, and thus come into direct contact with the current collector exposed between the induction nucleation parts. Therefore, compared with the case that the induction deposition layer entirely covers the current collector, the electrical conductivity between the film of black phosphorus and the current collector is better in this specific example.

It can be understood that with further progress of the deposition, multiple films of black phosphorus can be fused into one piece when they are in contact with each other during the growth toward the surrounding areas, so that a larger film of black phosphorus can be obtained.

In some specific examples of the present embodiment, the thickness of the induction deposition layer is smaller than or equal to 5 nm. Optionally, the thickness of the induction deposition layer is 2 nm to 5 nm. Controlling the thickness of the induction deposition layer between 2 nm and 5 nm not only ensures that the induction deposition layer has an ordered lattice to facilitate the epitaxial growth of the film of black phosphorus, but also avoids overlarge height difference between the film of black phosphorus growing beyond the induction deposition layer and the current collector. The overlarge height difference may lead to cracks of the film, and avoiding this is beneficial to maintain the integrity of the film of black phosphorus and the full contact between the film of black phosphorus and the current collector.

In some specific examples of the present embodiment, the metal in the phosphorus-containing alloy in the induction deposition layer includes one or more of gold, tin, silver, copper, lead, or indium. Optionally, the phosphorus-containing alloy in the induction deposition layer includes gold and tin. For example, the material of the induction deposition layer is an alloy containing phosphorus, gold, and tin.

In some specific examples of the present embodiment, the thickness of the film of black phosphorus is 1 μm to 50 μm. When the film of black phosphorus is too thin, the specific capacity per unit area of the film of black phosphorus as an active material is relatively small. When the film of black phosphorus is too thick, it is difficult to charge and discharge the black phosphorus at the surface of the film of black phosphorus.

Optionally, the thickness of the film of black phosphorus formed by deposition can be controlled to be 2 μm to 30 μm. For example, the thickness of the film of black phosphorus formed by deposition can be controlled to be 2 μm, 5 μm, 10 μm, 15 μm, 20 μm, 30 μm, or the ranges between the above-described thicknesses.

In some specific examples of the present embodiment, there are one or more films of black phosphorus, and the lateral dimension of each of the films of black phosphorus is larger than or equal to 100 μm.

The “lateral dimension” means the distance between two points that are farthest to each other in the surface of the film of black phosphorus. It can be understood that the lateral dimension of a single film of black phosphorus can at most cover the entire surface of the current collector. By controlling the lateral dimension of the single film of black phosphorus to be as large as possible, the relatively complete lattice structure of the film of black phosphorus can be ensured, so as to avoid the problem of poor electrical conductivity between multiple black phosphorus nanosheets in the traditional technology to the greatest extent.

Although the film of black phosphorus prepared by the magnetron sputtering includes spontaneously formed fine pores, the generation and distribution of these pores have certain randomness, and the size of these pores is relatively limited. According to an embodiment of the present disclosure, the following solution is further provided.

In some specific examples of the present embodiment, the surface of the film of black phosphorus further includes laser-ablated holes. The black phosphorus in the ablated portion of the film of the black phosphorus can be directionally removed through a laser ablation method, which has good controllability and limited damage to the film of black phosphorus, and the formed pores in the surface of the film of black phosphorus can be relatively large to accommodate the volume change. The laser-ablated holes are suitable for the case where the film of black phosphorus has a large thickness, for example, with the thickness larger than or equal to 30 μm.

In some specific examples of the present embodiment, the laser-ablated holes are plural, and the diameter of each laser-ablated hole is smaller than or equal to 0.1 mm. Optionally, the diameter of the laser-ablated hole is smaller than or equal to 0.05 mm.

In order to facilitate understanding of implementation way of the above-described film of black phosphorus, according to another embodiment of the present disclosure, a method for preparing the film of black phosphorus in the above-described embodiments is further provided, and the method includes the following steps:

forming an induction deposition layer on the current collector; and disposing the current collector formed with the induction deposition layer in a magnetron sputtering chamber, and depositing the film of black phosphorus on the induction deposition layer by magnetron sputtering.

In some specific examples of the present embodiment, the process of depositing the film of black phosphorus includes a plurality of deposition stages. Phosphorus atoms are controlled to be sputtered toward local areas of the surface of the current collector in respective deposition stages, and the areas to which the phosphorus atoms are sputtered in adjacent deposition stages are not completely overlapped, so as to further improve the looseness of the film of black phosphorus.

In some specific examples of the present embodiment, the method for forming the induction deposition layer can include: first depositing a metal substrate on the surface of the current collector; and then bombarding a target containing desired atoms to deposit the atoms from the target on the surface of the metal substrate; and then heating the metal substrate to form the phosphorus-containing alloy. It can be understood that, in addition to the phosphorus target, the target containing the desired atoms can also include targets of other metals in the phosphorus-containing alloy.

In some specific examples of the present embodiment, in the process of forming the induction deposition layer, a catalyst can also be deposited on the surface of the metal thin film to promote the alloying reaction of the metal thin film with other elements.

In some specific examples of the present embodiment, in the process of forming the film of black phosphorus on the induction deposition layer, the adopted phosphorus target is a black phosphorus target. Compared with red phosphorus, black phosphorus is more stable and passive, and thus the growing rate of the film of black phosphorus is relatively slow, which is conducive to the formation of a loose film of black phosphorus.

In some specific examples of the present embodiment, the thickness of the induction deposition layer is controlled to be smaller than or equal to 5 nm. Optionally, the thickness of the induction deposition layer is 2 nm to 5 nm.

In some specific examples of the present embodiment, the thickness of the film of black phosphorus formed by deposition is controlled to be 1 μm to 50 μm. Optionally, the thickness of the film of black phosphorus formed by deposition can be controlled to be 2 μm to 30 μm. For example, the thickness of the film of black phosphorus formed by deposition can be controlled to be 2 μm, 5 μm, 10 μm, 15 μm, 20 μm, 30 μm, or the ranges between the above-described thicknesses.

In some specific examples of the present embodiment, one or more films of black phosphorus are controlled to be formed by deposition, and the lateral dimension of each of the films of black phosphorus is larger than or equal to 100 μm.

In some specific examples of the present embodiment, after the depositing the film of black phosphorus, the method further includes the step of laser ablating portions of the film of black phosphorus.

In some specific examples of the present embodiment, in the step of laser ablating portions of the film of black phosphorus, the size of the laser spot is controlled to be smaller than or equal to 0.1 mm, and multiple locations in the film of black phosphorus are ablated. Optionally, the size of the laser spot can be controlled to be smaller than or equal to 0.05 mm.

Further, the present disclosure also provides a lithium ion battery, which includes a cathode electrode, a separator and an anode electrode. The cathode electrode and the anode electrode are opposite to each other. The separator is disposed between the cathode electrode and the anode electrode. The anode electrode is the black phosphorus anode electrode of the above-described embodiments.

In order to facilitate the understanding of the present disclosure, the following more specific and detailed experimental examples and comparative examples that are easier to implement are also provided below for reference. Various embodiments of the present invention and their advantages will also be apparent from the descriptions and performance results of the following specific experimental examples and comparative examples.

Unless otherwise specified, the raw materials used in the following examples and comparative examples can be conventionally purchased from the market.

### Example 1

A copper foil is used as a substrate. The power of the magnetron sputtering is controlled to be 300 W. Metal tin films with a thickness of 50 nm are sputtered onto opposite surfaces of the copper foil to form a current collector. The temperature in the chamber is controlled to be room temperature. A black phosphorus target and a gold target are bombarded to sputter phosphorus and gold onto multiple local areas of the metal tin surfaces. Then the temperature in the chamber is increased to 510° C. and kept for 30 minutes, so that tin, phosphorus, and gold together form an alloy with a thickness of about 3.5 nm as an induction deposition layer.

The temperature in the chamber is controlled to be room temperature. The power of the magnetron sputtering is controlled to be 400 W. A black phosphorus target is bombarded to grow a film of black phosphorus on the induction deposition layer. During the growth process, multiple films of black phosphorus are fused into one piece until the thickness of the film of black phosphorus reaches 10 μm.

### Example 2

A copper foil is used as a substrate. The power of the magnetron sputtering is controlled to be 300 W. Metal tin films with a thickness of 50 nm are sputtered onto opposite surfaces of the copper foil to form a current collector. The temperature in the chamber is controlled to be room temperature. A black phosphorus target and a gold target are bombarded to sputter phosphorus and gold onto multiple local areas of the metal tin surfaces. Then the temperature in the chamber is increased to 510° C. and kept for 30 minutes, so that tin, phosphorus, and gold together form an alloy with a thickness of about 3.5 nm as an induction deposition layer.

The temperature in the chamber is controlled to be room temperature. The power of the magnetron sputtering is controlled to be 400 W. A black phosphorus target is bombarded to grow multiple films of black phosphorus on the induction deposition layer. During the growth process, the multiple films of black phosphorus are fused into one piece until the thickness of the film of black phosphorus reaches 30 μm.

### Example 3

A copper foil is used as a substrate. The power of the magnetron sputtering is controlled to be 300 W. Metal tin films with a thickness of 50 nm are sputtered onto opposite surfaces of the copper foil to form a current collector. The temperature in the chamber is controlled to be room temperature. A black phosphorus target and a gold target are bombarded to sputter phosphorus and gold onto the opposite surfaces of the copper foil. Then the temperature in the chamber is increased to 510° ° C. and kept for 30 minutes, so that tin, phosphorus, and gold together form an alloy with a thickness of about 3.5 nm as an induction deposition layer.

The temperature in the chamber is controlled to be room temperature. The power of the magnetron sputtering is controlled to be 400 W. A black phosphorus target is bombarded to grow a film of black phosphorus on the induction deposition layer. During the growth process, multiple films of black phosphorus are fused into one piece until the thickness of the film of black phosphorus reaches 30 μm.

The surface of the film of black phosphorus is irradiated by using a laser with a spot diameter of 50 μm at intervals of 6 mm according to a preset program to form laser-ablated holes.

### Comparative Example 1

A copper foil is used as a substrate. Metal tin films with a thickness of 50 nm are sputtered onto opposite surfaces of the copper foil to form a current collector. The temperature in the chamber is controlled to be room temperature. A black phosphorus target and a gold target are bombarded to sputter phosphorus and gold onto multiple local areas of the metal tin surfaces. Then the temperature in the chamber is increased to 510° C. and kept for 30 minutes, so that tin, phosphorus, and gold together form an alloy with a thickness of about 3.5 nm.

Black phosphorus nanosheets exfoliated off by using a solution method and graphene are mixed with a mass ratio of 4:1. The mixture is added with polyvinylidene fluoride as a binder and nitrogen methyl pyrrolidone as an organic solvent and stirred to form a slurry. The slurry is coated onto the surface of the above-described treated copper foil and dried to form an anode electrode layer with a thickness of about 10 μm.

### Comparative Example 2

A copper foil is used as a substrate. Metal tin films with a thickness of 50 nm are sputtered onto opposite surfaces of the copper foil to form a current collector. The temperature in the chamber is controlled to be room temperature. A black phosphorus target and a gold target are bombarded to sputter phosphorus and gold onto multiple local areas of the metal tin surfaces. Then the temperature in the chamber is increased to 510° C. and kept for 30 minutes, so that tin, phosphorus, and gold together form an alloy with a thickness of about 3.5 nm.

Black phosphorus nanosheets exfoliated off by using a solution method and graphene are mixed with a mass ratio of 4:1. The mixture is added with polyvinylidene fluoride as a binder and nitrogen methyl pyrrolidone as an organic solvent and stirred to form a slurry. The slurry is coated onto the surface of the above-described treated copper foil and dried to form an anode electrode layer with a thickness of about 30 μm.

### Comparative Example 3

A copper foil is used as a substrate. The power of the magnetron sputtering is controlled to be 300 W. Metal tin films with a thickness of 50 nm are sputtered onto opposite surfaces of the copper foil to form a current collector. The temperature in the chamber is controlled to be room temperature. A black phosphorus target and a gold target are bombarded to sputter phosphorus and gold onto multiple local areas of the metal tin surfaces. Then the temperature in the chamber is increased to 510° C. and kept for 30 minutes, so that tin, phosphorus, and gold together form an alloy with a thickness of about 3.5 nm as an induction deposition layer.

The above-treated copper foil is transported to a chemical vapor deposition chamber, the temperature thereof is maintained at 500° C., and red phosphorus vapor is introduced into the chamber to form a film of black phosphorus with a thickness of 10 μm along the induction deposition layer on the surface of the current collector.

Tests: The black phosphorus anode electrodes prepared by the above-described examples and comparative examples are used as the anode electrodes. The counter electrode is a lithium sheet. The electrolyte is lithium hexafluorophosphate dissolved in a mixed solvent of ethylene carbonate and diethyl carbonate. In the electrolyte, a volume ratio of ethylene carbonate and diethyl carbonate is 1:1, and a concentration of lithium hexafluorophosphate is 1 mol/L. A polypropylene separator is disposed between the lithium sheet and the black phosphorus anode electrode to assemble a button-type battery. The battery performance of each example and comparative example is tested at a charge-discharge current of 100 mA/g. The battery performance includes the initial discharge specific capacity and the discharge specific capacity after 50 cycles. The results can be seen in Table 1.

TABLE 1

| | Initial discharge | Discharge specific | |
|---|---|---|---|
| | specific capacity | capacity after 50 | Capacity |
| | (mAh/g) | cycles (mAh/g) | loss |
| Example 1 | 1414 | 1325 | 6.29% |
| Example 2 | 1350 | 1242 | 8.00% |
| Example 3 | 1620 | 1565 | 3.40% |
| Comparative | 914 | 702 | 23.19% |
| Example 1 | | | |
| Comparative | 865 | 542 | 37.34% |
| Example 2 | | | |
| Comparative | 1320 | 587 | 55.53% |
| Example 3 | | | |

According to Table 1, it can be seen that the initial discharge specific capacities of Example 1, Example 2 and Example 3 are all much higher than those of Comparative Example 1 and Comparative Example 2. This is mainly because the films of black phosphorus of Examples 1 to 3 are directly deposited and grown on the current collectors.

The contact area between the films of black phosphorus and the current collectors is relatively large, and the electrical contact between the films of black phosphorus and the current collectors is superior, so that the capacity of the active material is used more completely during charge and discharge. In addition, the capacity retention rates of Examples 1 to 3 are also obviously better than those of Comparative Example 1 and Comparative Example 2. This is mainly because the films of black phosphorus grown by magnetron sputtering include pores, which can buffer the volume change, and have better internal bonding performance and are therefore not easy to be detached off, so the capacity retention rates are also significantly improved. Moreover, in Comparative Example 3, the film of black phosphorus is grown by using the chemical vapor deposition method, and the initial discharge specific capacity is obviously relatively high. This is mainly because the good integrity of the film of black phosphorus epitaxially grown by chemical vapor deposition and the better electrical contact between the film of black phosphorus and the current collector. However, there is a very obvious capacity loss in the subsequent cycling process, which is mainly because the film of black phosphorus prepared has good lattice integrity and high density, which is not conducive to the volume change in charge and discharge process.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present application.

The above-described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims. The specification and drawings are for the purpose of explaining the contents of the claims.

1. A black phosphorus anode electrode comprising a current collector, an induction deposition layer, and a film of black phosphorus, wherein the induction deposition layer is disposed on the current collector, the induction deposition layer comprises a phosphorus-containing alloy configured to induce deposition of the film of black phosphorus, the film of black phosphorus is formed on the induction deposition layer by magnetron sputtering, and the film of black phosphorus covers the current collector.

2. The black phosphorus anode electrode of claim 1, wherein a thickness of the film of black phosphorus is about 1 μm to about 50 μm.

3. The black phosphorus anode electrode of claim 1, wherein the film of black phosphorus is one or more films of black phosphorus, and lateral dimension of each of the one or more films of black phosphorus is larger than or equal to 100 μm.

4. The black phosphorus anode electrode of claim 1, wherein the induction deposition layer comprises a plurality of induction nucleation parts spaced apart from each other, each of the plurality of induction nucleation parts comprises the phosphors-containing alloy, and the current collector is exposed between the plurality of the induced nucleation parts.

5. The black phosphorus anode electrode of claim 1, wherein a thickness of the induction deposition layer is smaller than or equal to 5 nm.

6. The black phosphorus anode electrode of claim 1, wherein the film of black phosphorus further comprises a laser-ablated hole.

7. The black phosphorus anode electrode of claim 6, wherein the laser-ablated hole is a plurality of laser-ablated holes, and a diameter of each of plurality of the laser-ablated holes is smaller than or equal to 0.1 mm.

8. The black phosphorus anode electrode of claim 1, wherein the induction deposition layer and the film of black phosphorus are disposed on each of opposite surfaces of the current collector.

9. A method for preparing a black phosphorus anode electrode, the black phosphorus anode electrode comprising a current collector, an induction deposition layer, and a film of black phosphorus, wherein the induction deposition layer is disposed on the current collector, the induction deposition layer comprises a phosphorus-containing alloy configured to induce deposition of the film of black phosphorus, the film of black phosphorus is formed on the induction deposition layer by magnetron sputtering, and the film of black phosphorus covers the current collector; the method comprising following steps:
forming the induction deposition layer on the current collector;
disposing the current collector formed with the induction deposition layer in a magnetron sputtering chamber, and depositing the film of black phosphorus on the induction deposition layer by magnetron sputtering.

10. The method of claim 9, wherein a thickness of the film of black phosphorus is about 1 μm to about 50 μm.

11. The method of claim 9, wherein the film of black phosphorus is one or more films of black phosphorus, and lateral dimension of each of the one or more films of black phosphorus is larger than or equal to 100 μm.

12. The method of claim 9, wherein the induction deposition layer comprises a plurality of induction nucleation parts spaced apart from each other, each of the plurality of induction nucleation parts comprises the phosphors-containing alloy, and the current collector is exposed between the plurality of the induced nucleation parts.

13. The method of claim 9, wherein a thickness of the induction deposition layer is smaller than or equal to 5 nm.

14. The method of claim 9, wherein the film of black phosphorus further comprises a laser-ablated hole.

15. The method of claim 14, wherein the laser-ablated hole is a plurality of laser-ablated holes, and a diameter of each of the plurality of laser-ablated holes is smaller than or equal to 0.1 mm.

16. The method of claim 9, wherein the induction deposition layer and the film of black phosphorus are disposed on each of opposite surfaces of the current collector.

17. A lithium ion battery comprising a cathode electrode, a separator and an anode electrode, wherein the cathode electrode and the anode electrode are opposite to each other, the separator is disposed between the cathode electrode and the anode electrode, the anode electrode is a black phosphorus anode electrode, and the black phosphorus anode electrode comprises a current collector, an induction deposition layer, and a film of black phosphorus, the induction deposition layer is disposed on the current collector, the induction deposition layer comprises a phosphorus-containing alloy configured to induce deposition of the film of black phosphorus, the film of black phosphorus is formed on the induction deposition layer by magnetron sputtering, and the film of black phosphorus covers the current collector.

18. (canceled)

19. (canceled)

20. The lithium ion battery of claim 17, wherein the induction deposition layer comprises a plurality of induction nucleation parts spaced apart from each other, each of the plurality of induction nucleation parts comprises the phosphors-containing alloy, and the current collector is exposed between the plurality of the induced nucleation parts.

21. (canceled)

22. The lithium ion battery of claim 17, wherein the film of black phosphorus further comprises a laser-ablated hole.

23. (canceled)

24. The lithium ion battery of claim 17, wherein the induction deposition layer and the film of black phosphorus are disposed on each of opposite surfaces of the current collector.
